(19) United States
(12) Patent Application Publication
(10) Pub. No.: US 2012/0112256 A1
(43) Pub. Date: May 10, 2012

(54) Control gate structure and method of forming a control gate structure

(75) Inventors: Shyue Seng Tan, Singapore (SG); Ying Keung Leung, Singapore (SG); Elgin Quek, Singapore (SG)

(73) Assignee: Globalfoundries Singapore Pte, Ltd., Singapore (SG)

(21) Appl. No.: 12/925,991

(22) Filed: Nov. 4, 2010

(51) Int. Cl. H01L 29/68; H01L 21/71

(52) U.S. Cl. 257/296; 257/316; 438/585; 257/E29.17; 257/E21.536

(57) ABSTRACT

Semiconductor devices and methods of fabricating the devices are provided. An example device may include a substrate and a gate structure on the substrate. The gate structure includes a control gate having at least three distinct gate regions. First and second control gate regions are configured as a first field type, such as a high-gate or low-gate type. A third control gate region configured as a second field type (different from the first field type) is at least partially disposed between the first and second control gate regions.

### TECHNICAL FIELD

The present disclosure relates generally to semiconductor devices and methods of fabrication of semiconductor devices and, more particularly, to the fabrication of a control gate structure for non-volatile memory applications.

### BACKGROUND

A conventional split gate, thin film storage device 10 is depicted in FIG. 1. The device 10 includes a select gate 12 and a control gate 14. Device 10 further includes a charge storage layer 16 between select gate 12 and control gate 14, which also extends between control gate 14 and substrate 18. Device 10 further includes a source 20 and a drain 22.

As shown in FIG. 2, the conventional split gate, thin film storage device 10 suffers from certain drawbacks. For instance, there is a non-uniformity of the e-field. Specifically, there is created a high field at the region between the control gate 14 and the select gate 12. This results in non-uniform charge trapping because only nanocrystals near the control gate 14 receive charges. This causes inefficiency in programming. As shown in FIG. 2, for example, the conventional device 10 results in a low-field region 23 due to nearly uniform inversion charge in the linear region. There is also created a high-field region 24 and an inverse-charge region 25.

A further drawback of the conventional device is that depending on the proximity and potential difference between adjacent nanocrystals, and imperfections of the gate-edge nanocrystals due to the implantation and etching processes, there can be excessive cross-talk and data leakage. This can result in retention problems.

Some conventional solutions have involved modulating the lateral e-field by employing an implantation step. This involves an implantation at the halo/extension and/or source/drain region. An illustration of this solution and its resulting lateral e-field is provided in FIG. 3. It can be seen that the resulting lateral e-field has a peak field near the drain region.

Other solutions have involved gate work function modulation to control the lateral e-field. Examples of these solutions and their resulting lateral e-fields are provided in FIGS. 4 and 5. FIG. 4 illustrates an H-L gate work function that results in a peak field near the center of the charge storage channel. FIG. 5 illustrates an L-H gate work function that results in a peak field near the drain region.

These modulation techniques have been used to provide, for example, Ion-Ioff, improved Gm-Rout, and improved HCl immunity. However, the work function between the high and low gates (as in FIGS. 4 and 5) causes an abrupt change in the conduction band energy at the silicon surface creating the illustrated peaks in the lateral e-field. As can be seen in FIGS. 3-5, these solutions still result in non-uniformity of the lateral e-field.

### SUMMARY

According to one embodiment, a method is provided for forming a semiconductor device. The method includes providing a substrate and forming a gate structure on the substrate. The gate structure includes a control gate and a select gate, and the control gate is configured or formed to include three or more alternating high-gate and low-gate regions.

According to another embodiment, a semiconductor device is provided having a substrate and a gate structure disposed on the substrate. The gate structure has a select gate and a control gate, and the control gate includes at least three alternating high-gate and low-gate regions.

The resulting structures with a high-low-high control gate or a low-high-low control gate may benefit from some, none, or all of certain advantages. Among other things, the structures provide a more uniform e-field, which in turn allows for more uniform injection. Stated otherwise, there are more injection sites than prior art devices, which provides for improved programming. Improved programming entails faster non-volatile programming as compared to the prior art as well as improvements in data retention due to suppression of cross-talk between adjacent nanocrystals in the structure.

Particular ones of the various embodiments may result in some, none, or all of the described advantages. Other technical features may be readily apparent to one skilled in the art from the following figures, descriptions, and claims.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects, and in which:

FIG. 1 is an illustration of a prior art split gate, thin film storage device;

FIG. 2 is an illustration of the lateral e-field distribution of the prior art split gate, thin film storage device of FIG. 1;

FIG. 3 is an illustration of a gate device with implantation e-field modulation and a resulting e-field;

FIG. 4 is an illustration of a gate device employing a high-low gate work function and a resulting e-field;

FIG. 5 is an illustration of a gate device employing a low-high gate work function and a resulting e-field;

FIG. 6 is an illustration of a split gate semiconductor device according to one embodiment;

FIG. 7 is an illustration of the e-field modulation associated with the split gate semiconductor device of FIG. 6;

FIG. 8 is an illustration of a split gate semiconductor device according to one embodiment;

FIG. 9 is an illustration of the e-field modulation associated with the split gate semiconductor device of FIG. 8; and

FIGS. 10-22 illustrate various steps in the fabrication of a split gate semiconductor device according to an embodiment.

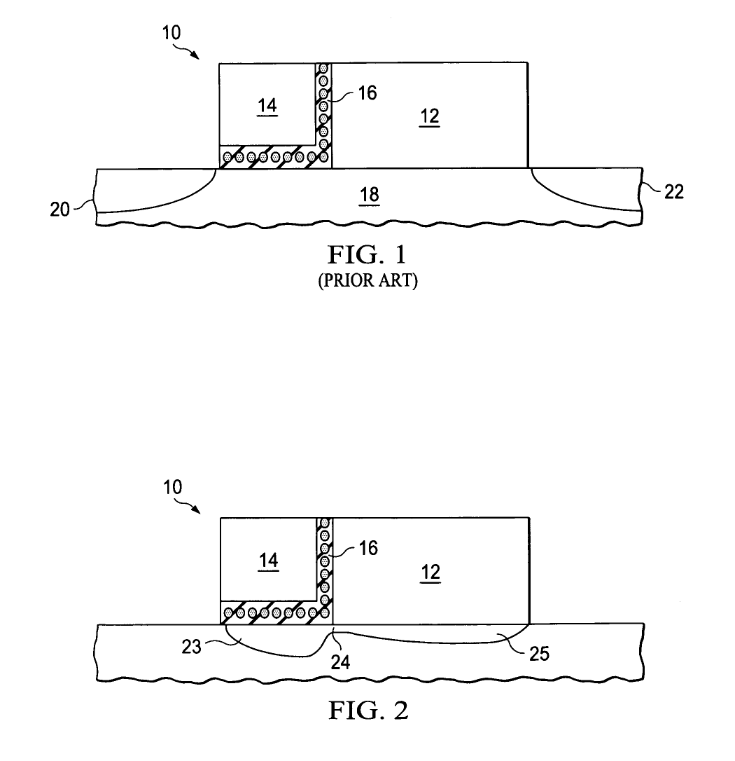

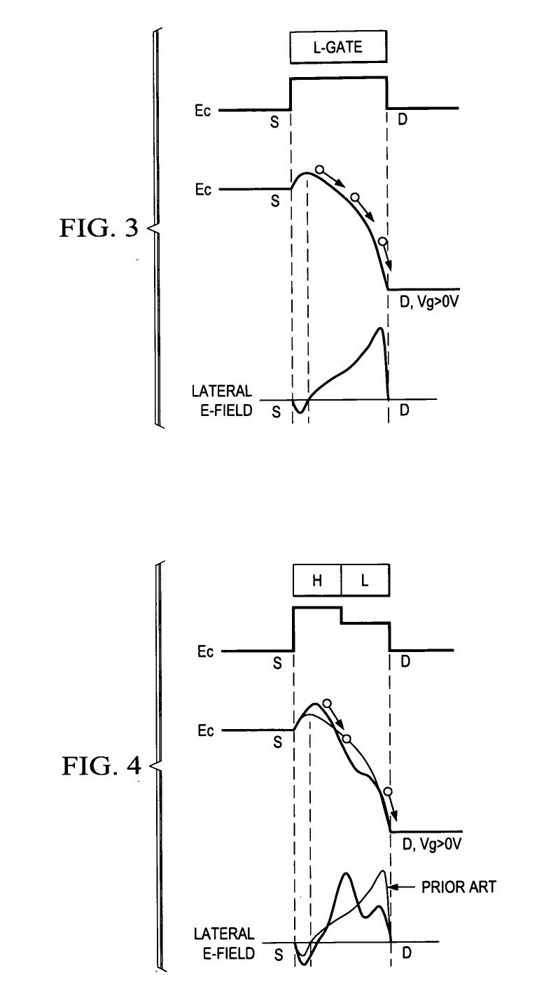

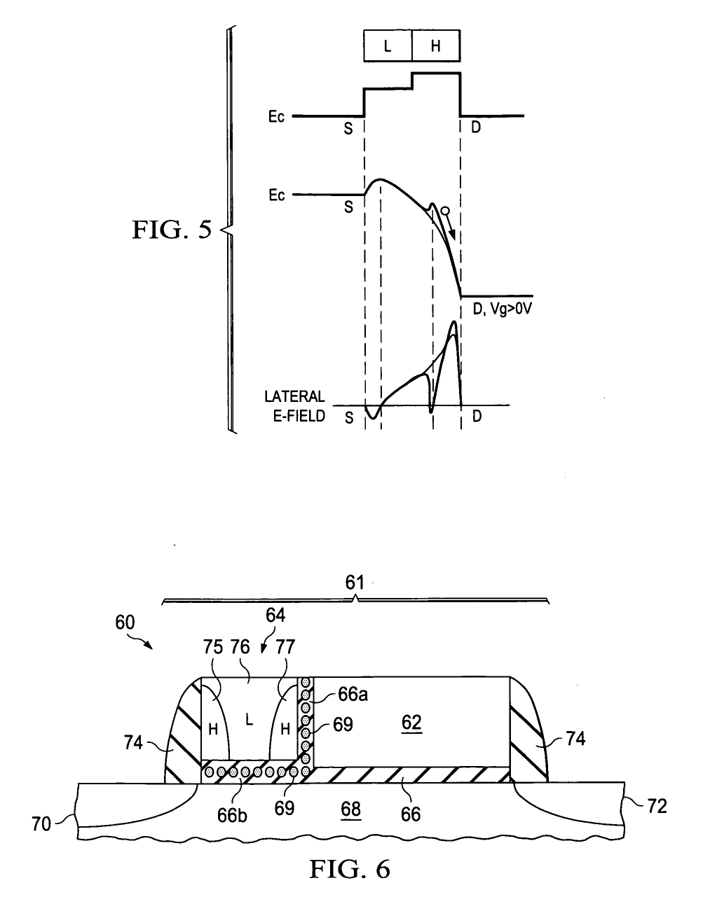

### DETAILED DESCRIPTION

According to various embodiments, a split gate semiconductor structure is provided. This structure can be incorporated into a semiconductor device, which may be used in a non-volatile memory device. It should be understood that this is but one application of the structure and the structure may be incorporated into other semiconductor devices that employ a gate-type architecture.

FIG. 6 illustrates one embodiment of such of a structure in accordance with the present disclosure. It should be understood that this is an example only, and that there are other embodiments that employ variations of the structure depicted in FIG. 6.

As shown in FIG. 6, a device 60 includes a substrate 68 upon which a gate structure is disposed. The gate structure 61 is shown as a split gate structure, which includes a select gate 62 and a control gate 64. It should be understood that the gate structure may include any other applicable components as desired to achieve a semiconductor structure useful in a desired device. The split gate structure 61 further includes a charge storage channel 66 disposed between the control gate 64 and the select gate 62 (the vertical portion 66a) and also disposed between the control gate 64 and the substrate 68 (the horizontal portion 66b). The device 60 also includes a source region 70, a drain region 72, and sidewall spacers 74 disposed outwardly from the control gate 64 and the select gate 62 (as shown), respectively.

Substrate 68 may include any suitable substrate material or combination of materials such as, for example, a p-well doped semiconductor substrate formed from gallium arsenide, silicon germanium, silicon-on-the-insulator, silicon, monocrystalline silicon, and so forth. Select gate 62 is generally a gate oxide material (formed by poly deposition), and may include any suitable materials for a gate structure. Charge storage channel 66 may include any suitable material or combination of materials, such as a tunnel oxide and/or a top oxide, and further may include nanocrystals 69 disposed therein or therebetween. The nanocrystals 69 may be any suitable material such as, for example, silicon, poly-silicon, germanium, and the like. Source region 70 and drain region 72 may be formed from any suitable materials, such as, for example, known n-doped source and drain implant materials. Spacers 74 are formed of oxide (e.g., silicon dioxide) or other suitable insulating material(s).

Control gate 64 is formed of a plurality of gate components 75, 76, and 77. The first gate component 75 is formed as a high-gate component, the second gate component 76 is formed as a low-gate component, and the third gate component 77 is formed as a high-gate component. The terms “high-gate” and “low-gate” are generally understood in the art. The term “high-gate” generally means high work-function gate material (for example, P-type doped poly-silicon) and “low-gate” generally means low work-function gate material (for example, N-type doped poly-silicon).

In the depicted embodiment, the orientation of the gate components 75, 76, 77 of the control gate 64 may be modified as shown, for example, in FIG. 8. FIG. 8 illustrates a device 260 having the substrate 68 and a split gate structure 261 disposed thereon. Device 260 is similar to device 60 depicted in FIG. 6 but includes a control gate 264. Control gate 264 is formed of a plurality of gate components (or regions) 275, 276, and 277. The first gate component 275 is formed as a low-gate component, the second gate component 276 is formed as a high-gate component, and the third gate component 277 is formed as a low-gate component.

Thus, for the device 60, 260 shown in FIG. 6 and FIG. 8, respectively (or any suitable modification of such a devices), the control gate includes at least three regions of alternating gate regions. The device 60 includes alternating H-L-H gate components, while the device 260 includes alternating L-H-L gate components. Though in one embodiment there are three gate components, it will be understood that the control gate structure may be configured with three or more gate components. In another embodiment, as shown in FIGS. 6 and 8, the outer gate components of the control gate are of the same type. That is, the outer control gate regions are either both high-gate regions or both low-gate regions. As will be appreciated, this embodiment will generally require an odd number of gate components.

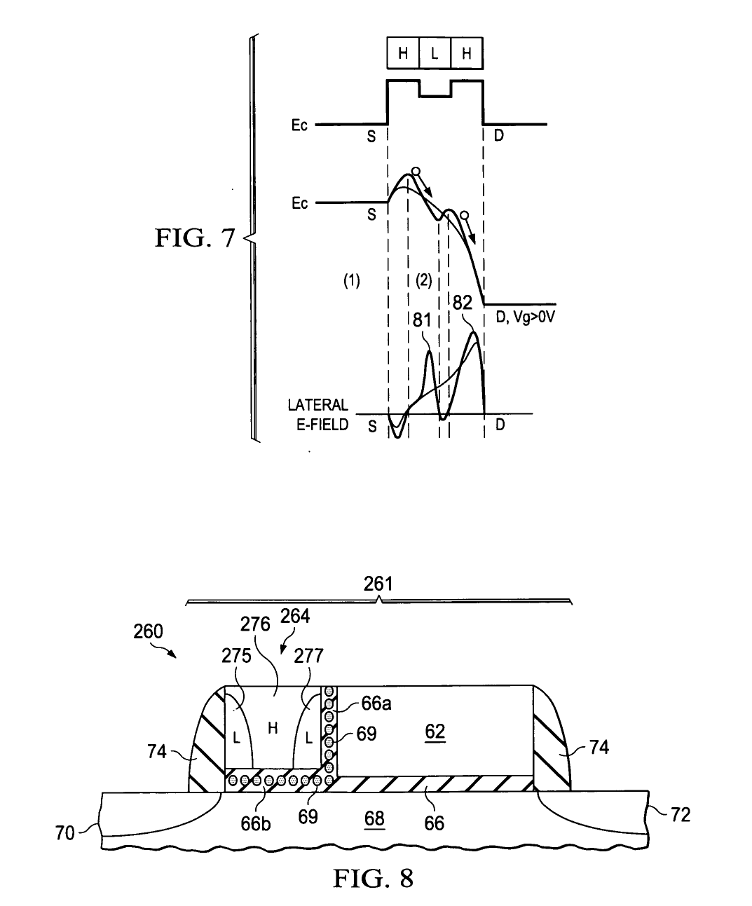

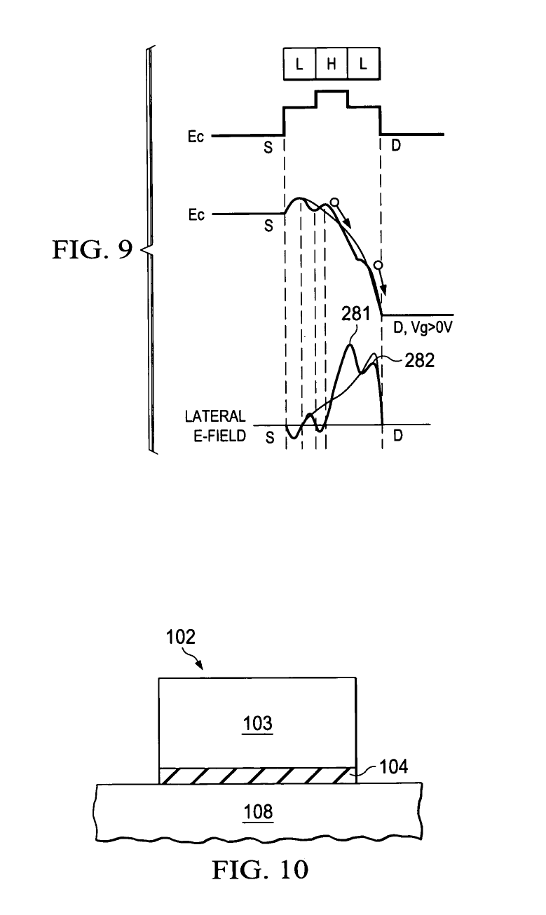

FIGS. 7 and 9, respectively, illustrate the e-fields resulting from employing a high-low-high control gate structure (as shown in FIG. 6) or a low-high-low control gate structure (as shown in FIG. 8).

Turning to FIG. 7, the configuration of the high-low-high regions (75, 76, 77) of the control gate 64 results in an e-field having two peak fields 81, 82. Preferably the two peak fields 81, 82 are both higher field than provided in prior devices. It is also preferable that the two peak fields 81, 82 are adapted to, or capable of, providing a high e-field effect to carrier injection. The first peak field 81 shown in FIG. 7 (resulting from the high-low-high gate structure of the control gate 64) is located generally beneath the low-gate region 76 and near the center of the horizontal portion 66b of the charge storage channel 66. The second peak field 82 shown in FIG. 7 is located generally beneath the high-gate region 77 and nearer to the drain region 72.

Turning to FIG. 9, the configuration of the low-high-low regions (275, 276, 277) of the control gate 264 results in an e-field having two peak fields 281, 282. The first peak field 281 shown in FIG. 9 (resulting from the low-high-low gate structure of the control gate 264) is located beneath the high-gate region 276 and positioned about at the interface between the high-gate region 276 and the low-gate region 277. The second peak field 282 shown in FIG. 9 is located beneath the low-gate region 277 and closer to the drain region 72.

A method of fabricating the devices 60, 260 described herein is illustrated in FIGS. 10-22. As illustrated in FIG. 10, a select gate 102 is formed by forming a conventional gate oxide layer 103 and a gate contact region 104 (and defining the gate by etchback). In one embodiment, the gate contact region 104 is formed of polysilicon (e.g., poly deposition). Other suitable materials may be used for the gate layer 102 and the gate contact region 103. The substrate 108 may be any suitable material known to those skilled in the art, including for example, silicon, gallium arsenide, silicon germanium, silicon-on-insulator, monocrystalline silicon, and the like.

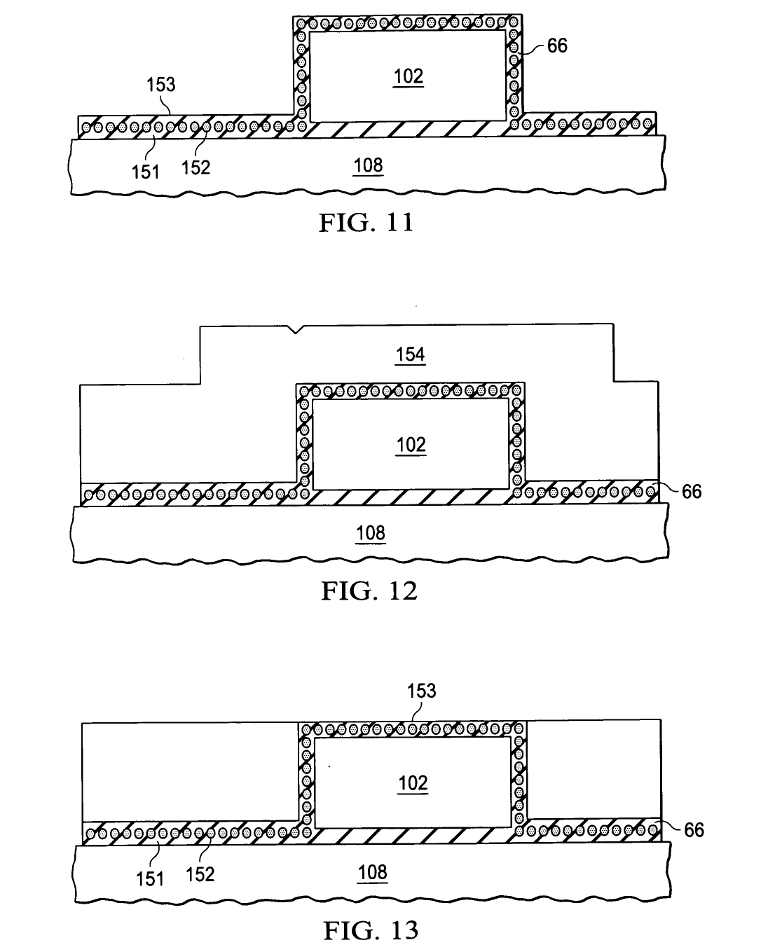

As illustrated in FIG. 11, a charge storage channel 66 is formed. The charge storage channel 66 may be formed by any suitable technique. As an example, the charge storage channel may be formed by-first growing a tunnel oxide layer 151 (e.g., 40-150 angstroms, 800-1050 degrees Celsius by dry/steam oxidation). Next is formed (e.g., grown) a layer 152 of material suitable to form nanocrystals 69. This layer 152 may include amorphous silicon, polysilicon, germanium or any other material suitable to form nanocrystals. After formation, the layer 152 is annealed (e.g., 750-1100 degrees Celsius, NO/N2, N2/O2, etc.) to form the nanocrystals 69. Next a top oxide layer 153 is formed above the layer 152/nanocrystals 69. In one embodiment, as shown in FIG. 11, the charge storage channel 66 extends along a first portion of the substrate 108, along a first sidewall of the select gate 102, across a top portion of the select gate 102, along a second sidewall of the select gate 102 and along a remaining second portion of substrate 108.

As illustrated in FIG. 12, a control gate layer 154 of polysilicon is deposited on the structure. The control gate layer 154 will ultimately form the control gate 64 of the device. Material(s) other than polysilicon may be used to form the layer 154 is suitable for a control gate layer. In one embodiment, the control gate layer 154 is formed over the entire structure.

As illustrated in FIG. 13, the control gate layer 154 is etched back to a level to form a top surface of the control gate 64. Preferably, the control gate lawyer 154 is etched back to a level substantially even with the upper surface of the top oxide layer 153 of the charge storage channel 66. This process may be formed by any suitable etch technique or, alternatively a chemical-mechanical planarization technique may be performed. Other techniques may be used to remove the desired portion of the control gate layer 154.

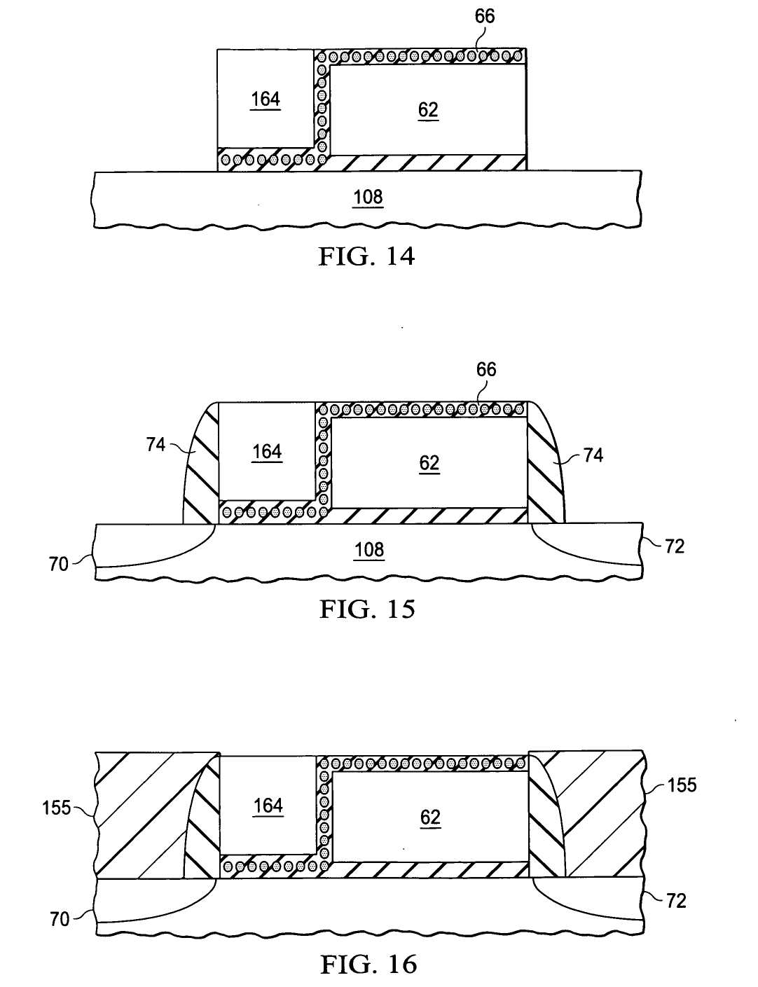

As illustrated in FIG. 14, additional control gate layer material is removed adjacent to what will become a temporary control gate structure 164. Control gate material is also removed adjacent the select gate 102 in order to form and defined a poly- or split-gate electrode structure 61 (semiconductor device) having a temporary control gate 164 and the select gate 62. In addition, any remaining portion of the charge storage channel 66 that extends along the substrate 108 in the directions away from the control gate 164 and the select gate 62, respectively, is removed. Also, any remaining portion(s) of the charge storage channel 108 that extends along the sidewall of the select gate 62 opposite the control gate 164 and extends along the substrate 108 from the select gate 62 and away from the control gate 164 is removed. This material removal step may be performed by any suitable etch or other material removal technique. Thus, the remaining structure is defined by a temporary control gate 164 and an adjacent select gate 62 disposed on the substrate 108, as shown in FIG. 14. This structure further includes the charge storage channel 66 extending underneath the temporary control gate 164 (i.e., between control gate 164 and substrate 108), between the temporary control gate 164 and the select gate 62, and along a top surface of the select gate 62.

As illustrated in FIG. 15, the source and drain regions 70, 72 are formed by, for example, any suitable implantation technique, such as implantation of known n-doped source/drain implant materials. In addition, a poly-reoxidation process may be employed to form halo/ext implants. As further illustrated, the sidewall spacers 74 are formed of suitable material, such as silicon oxide (dioxide) material.

As illustrated in FIG. 16, a blocking layer 155 is formed to provide a partial mask to protect the sidewall spacers 74 and adjacent substrate 108. The blocking layer 155 may be deposited by any suitable technique and is preferably initially deposited over the entire structure and material is removed to expose at least the temporary control gate 164. Any suitable material may be utilized, and in one embodiment, the blocking layer 155 is silicon nitride (Si3N4). Removal of material may be accomplished by any suitable technique including, for example, an etch-back process or chemical-mechanical planarization.

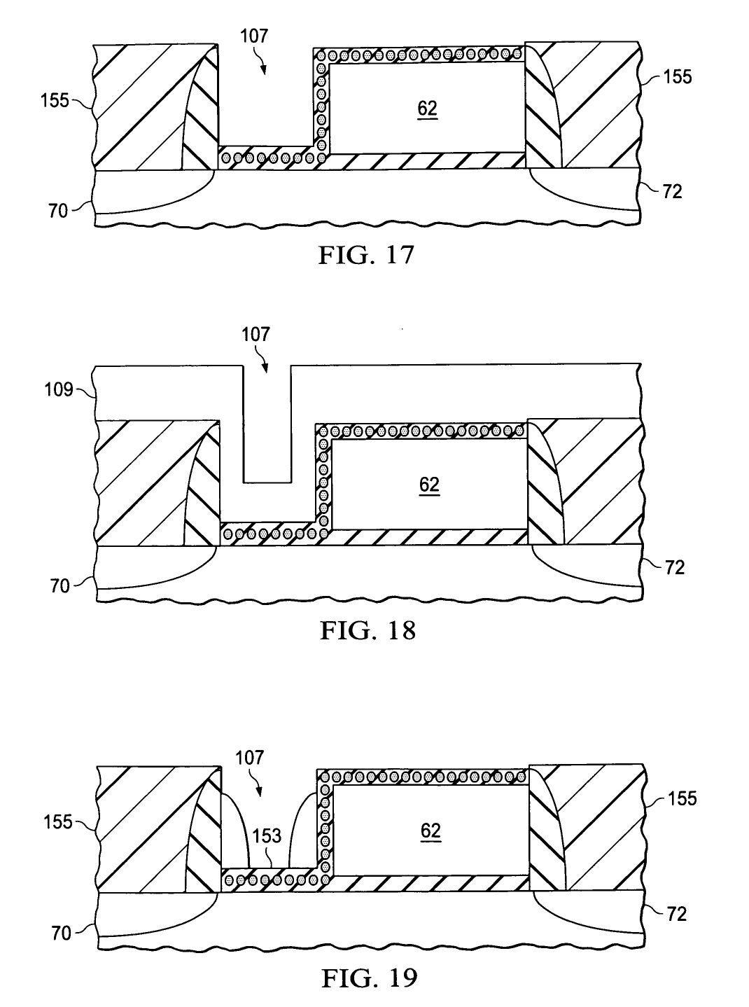

As illustrated in FIG. 17, the temporary control gate 164 is removed using any suitable material removal process. The resulting structure therefore includes a control gate cavity 107 (as shown in FIG. 17) providing a void or space for eventual formation of the control gate 64.

As illustrated in FIG. 18, a high-gate material 109, such as polysilicon with impurities (e.g., P-type dopants), is formed within at least a portion of the cavity 107. In one embodiment, the material 109 is formed over the entire structure to begin the process of forming the high-gate regions of the control gate 64 of the device 60. In one embodiment, the material 109 is deposited using in-situ P-doped polysilicon. Other suitable formation techniques may be used that result in a P-doped high-gate material.

As will be appreciated, if the objective is to form the split gate device 260 (instead of the device 60) having a low-high-low control gate configuration (as described elsewhere herein), a low-gate material (e.g., polysilicon with in-situ N+-doping) will be formed at this point in the process. For high-gate and low-gate components, for example, in-situ doped P-type dopant (e.g., P or As) and N-type dopant (e.g., B, In, etc.) may be used, respectively. Implantation may also be utilized but an in-situ doping process is preferred.

As illustrated in FIG. 19, a portion of the high-gate material is removed by any suitable method(s) such as, for example, an etch-back process or chemical-mechanical planarization. This results in the formation of the two physically separated high-gate material regions 75, 77.

In one embodiment, this process is a multi-step process that includes first removing (planarizing) the high-gate material down to a level substantially even with the top of the oxide layer 153 positioned above the select gate 62. In a next process, the high-gate material formed on the charge storage channel 66 within the cavity 107 is removed so that a central portion of the charge storage channel 66 is exposed and the two high-gate material regions 75, 77 are formed. Preferably, the two regions 75, 77 of high-gate material remain in the control gate cavity 170. In one embodiment, these two regions are spacer-shaped due to utilization of an anisotropic removal/etching process. In one embodiment, the portions 75, 77 have a base lateral dimension greater than an upper lateral dimension.

In the embodiment shown in FIG. 19, an inwardly-facing edge of each portion 75, 77 (relative to the control gate cavity 170) may be curved from top to bottom. Additionally, the curved, inwardly facing sides of the two high-gate regions 75, 77 may be curved in a convex manner. The upper limits of the two high-gate regions 75, 77 may be disposed below an upper limit of the spacer 74 and/or may be disposed below the upper surface of the charge storage channel 66 disposed above the select gate 62. In other words, the high-gate region 75 of the control gate 62 is substantially physically separated from the other high-gate region 77 (and from the vertical portion 66a of the storage charge channel 66), is disposed further away from the select gate 62 than the other high-gate region 77, and is adjacent the outwardly-disposed spacer 74. In another embodiment, the high-gate region 75 is completely separated from the high-gate region 77. Preferably, the two high-gate regions 75, 77 are completely physically separated from each other.

The other high-gate region 77 is disposed on an inner limit of the control gate cavity 170 and adjacent the vertical portion 66a of the charge storage channel 66, which is adjacent the select gate 62. At this point in the process, there preferably remains a space between (and separating) the first and second high-gate portions 75, 77. This space extends at least partially along the vertical inwardly-facing sides of the first and second high-gate portions 75, 77. In one embodiment, the space extends substantially from the tops to the bottoms (i.e., along the height) of the inwardly-facing sides of the first and second high-gate portions of the control gate.

As will be readily understood, if a low-high-low control gate 264 is desired, then the low-gate material will be deposited and portions thereof removed in a manner similar to that described in connection with the deposit and removal of the high-gate material. Thus, first and second outwardly-disposed (relative to the control gate cavity) low-gate regions 275, 276 would be created. In other words, the first and second high gate regions 75, 77 described above would instead be low-gate regions 275, 277, but would be formed in the same or similar manner.

In one embodiment, in a typical 90 nm NVM process where the length of a control gate is on the order of about 120 to about 150nm, a lateral dimension of the high-gate regions 75, 77 can be on the order of about 10 to about 30 nm (i.e., 100 to 300 Angstroms). This will provide a lateral spacing dimension (at the base) between the two high-gate regions 75, 77 on the order of about 60 to about 130 nm. Preferably, regions 75 and 77 occupy about one-third each of total control gate length. As will be appreciated, the width of the high-gate regions 75, 77 may be adjusted to control the peak field. For example, two different H-L-H structures of 45%/10%/45% (proportion of total gate length) or 10%/80%/10%, respectively, can give rise to different final e-field distributions due to different abrupt changes of H-L transition regions caused by the different widths.

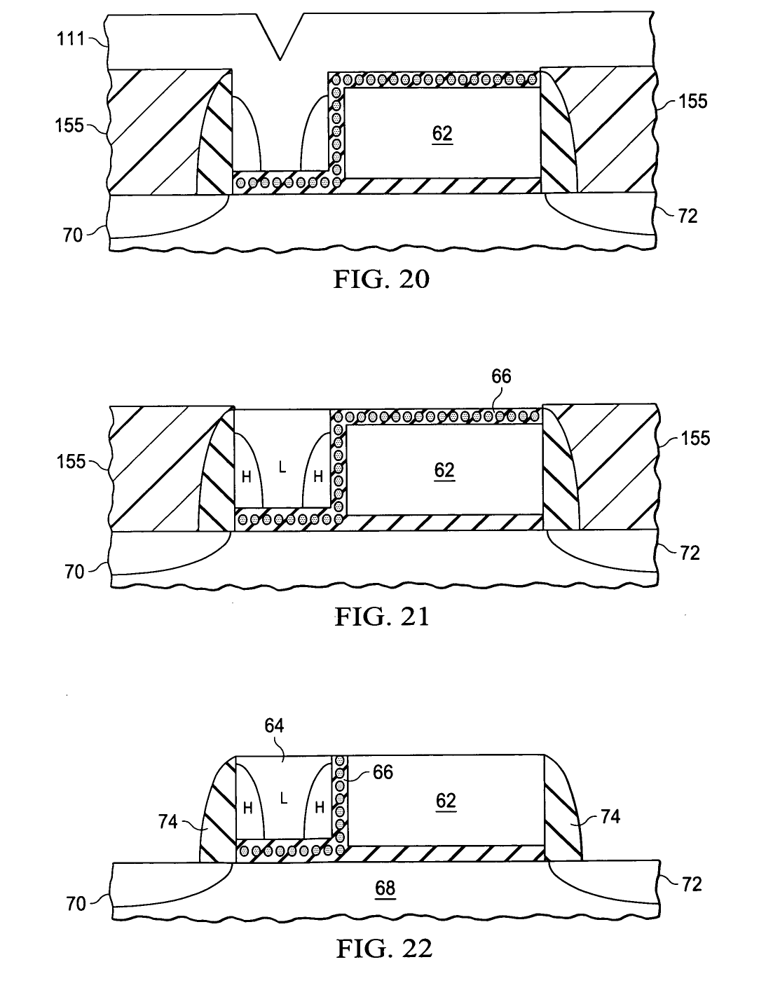

As illustrated in FIG. 20, a low-gate material 111, such as polysilicon with impurities (e.g., N-type dopants), is formed within the remaining space within the cavity 107. In one embodiment, the material 111 is formed over the entire structure to begin the process of forming the low-gate region 76 of the control gate 64 of the device 60. In one embodiment, the material 111 is deposited using in-situ N+-doped polysilicon. Other suitable formation techniques may be used that result in an N+-doped high-gate material. Similarly, if the objective is to form the split gate device 260 (instead of the device 60) having a low-high-low control gate configuration (as described elsewhere herein), a high-gate material (e.g., polysilicon with in-situ P+-doping) will be formed at this point in the process.

As illustrated in FIG. 21, a portion of the low-gate material 111 (or high-gate material for a low-high-low control gate) is removed utilizing a suitable material removal technique, such as an etch-back process or chemical-mechanical planarization. This results in the formation of the low-gate region 76 disposed between the two high-gate regions 75, 77. As shown, the resulting control gate 62 has a high-low-high configuration. At this point (or thereafter), the structure may be subjected to a thermal anneal (e.g., RTA and/or milisec-anneal) or other suitable process to activate the source and drain regions 70, 72.

Now turning to FIG. 22, the blocking layer 155 is removed, and the portion of the charge storage channel 66 above the select gate 62 is also removed (by any suitable technique, such as CMP or etch-back). At this point in the process, the desired split-gate semiconductor structure 60 is formed.

It should be understood that certain modifications to, or variations of, the methods and devices described herein are within the spirit and scope of the disclosure. For example, while certain embodiments have a control gate structure with at least three alternating high- and low-gate regions, other embodiments may have a control gate with multiple portions such that certain adjacent portions have the same field type. Thus, for example, a control gate might be a high-low-low-high-low-high control gate structure. This is within the scope of the disclosure, and within the meaning of alternating high- and low-gate (or alternating-low and high-gate). This is especially the case where there are at least three regions of the control gate and at least two of the regions are of one field type with at least one region of a different field type at least partially disposed between the two regions of the other type.

The resulting structure, with its high-low-high (or low-high-low) control gate may benefit from some, none, or all of certain advantages. Among other things, the structures provide a more uniform e-field, which in turn allows for more uniform injection. Stated otherwise, there are more injection sites, which provides for improved programming. Improved programming entails faster non-volatile programming as compared to the prior art as well as improvements in data retention due to suppression of cross-talk between adjacent nanocrystals in the structure.

It should be understood that the order of steps or processing described herein can be changed or varied. Though not shown, additional devices and structures may be created using the techniques described herein. It will be understood that well known processes have not been described in detail and have been omitted for brevity. Although specific steps, materials, material deposition and material removal techniques may have been described, the present disclosure is not necessarily limited to these specifics, and others may substituted as is well understood by those of ordinary skill in the art.

It may be advantageous to set forth definitions of certain words and phrases used throughout this patent document. The terms “include” and “comprise,” as well as derivatives thereof, mean inclusion without limitation. The term “or” is inclusive, meaning and/or. The phrases “associated with” and “associated therewith,” as well as derivatives thereof, mean to include, be included within, interconnect with, contain, be contained within, connect to or with, couple to or with, be communicable with, cooperate with, interleave, juxtapose, be proximate to, be bound to or with, have, have a property of, or the like.

While this disclosure has described certain embodiments and generally associated methods, alterations and permutations of these embodiments and methods will be apparent to those of ordinary skill in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method of forming a semiconductor device, the method comprising:
providing a substrate;
forming a gate structure on the substrate, the gate structure comprising a control gate and a select gate;
forming the control gate to comprise three or more gate regions having alternating field types.

2. The method of claim 1, wherein the step of forming the gate structure comprises forming a select gate and an adjacent control gate cavity, and wherein the step of forming the control gate comprises providing a high-gate material in the control gate cavity, removing a portion of the high-gate material to create a space, and filling the space with a low-gate material.

3. The method of claim 1, wherein the step of forming the gate structure comprises forming a select gate and an adjacent control gate cavity, and wherein the step of forming the control gate comprises providing a low-gate material in the control gate cavity, removing a portion of the low-gate material to create a space, and filling the space with a high-gate material.

4. The method of claim 1, wherein the formed control gate comprises two outwardly-disposed control gate portions having the same field type.

5. The method of claim 4, wherein the two outwardly-disposed control gate portions both comprise a high-gate material.

6. The method of claim 4, wherein the two outwardly-disposed control gate portions both comprise a low-gate material.

7. The method of claim 1, wherein the formed control gate comprises a first side control gate portion disposed at a first side of the control gate distal from the select gate and a second side control gate portion disposed at a second side of the control gate proximal to the select gate, at least one of the first and second control gate portions having an inwardly-disposed curved side.

8. The method of claim 7, wherein the inwardly-disposed curved side is convexly curved.

9. The method of claim 7, wherein the at least one of the first and second control gate portions having the inwardly-disposed curved side is spacer-shaped.

10. The method of claim 1, wherein the formed control gate comprises a first side control gate portion disposed at a first side of the control gate distal from the select gate and a second side control gate portion disposed at a second side of the control gate proximal to the select gate, at least one of the first and second control gate portions having a base dimension proximal to the substrate that is greater than an upper dimension distal from the substrate.

11. The method of claim 1, wherein the formed control gate comprises two outwardly-disposed control gate portions having different field types.

12. The method of claim 1, wherein the step of forming the control gate comprises forming two outer control gate portions and at least one inner control gate portion, the at least one inner control gate portion starting at an upper limit of the gate structure distal from the substrate and extending at least partially toward the substrate.

13. The method of claim 1, wherein the at least one inner control gate portion extends to a bottom limit of at least one of the two outwardly-disposed control gate portions.

14. A semiconductor device comprising:
a substrate;
a gate structure disposed on the substrate, the gate structure including a select gate and a control gate; and
wherein the control gate comprises at least three regions of alternating field types.

15. The device of claim 14, wherein the control gate comprises two outwardly-disposed high-gate portions and at least one low-gate portion disposed at least partially between the two high-gate portions.

16. The device of claim 14, wherein the control gate comprises two outwardly-disposed low-gate portions and at least one high-gate portion disposed at least partially between the two low-gate portions.

17. The device of claim 14, wherein the control gate comprises two outwardly-disposed gate portions having different field types and at least one gate portion disposed at least partially between the two outwardly-disposed gate portions.

18. The device of claim 17, wherein at least one of the two outwardly-disposed gate portions has at least one side that is curved.

19. The device of claim 14, wherein the control gate comprises two outwardly-disposed gate portions of a first field type and at least one gate portion of a second field type at least partially disposed between the two outwardly-disposed gate portions.

20. A non-volatile memory semiconductor device comprising:
a substrate;
a gate structure disposed on the substrate, the gate structure having a select gate, a control gate, and a charge storage channel disposed between the control gate and the select gate; and
wherein the control gate comprises first and second regions having a first field type and a third region having a second field type.
